(19) United States
(12) Patent Application Publication
(10) Pub. No.: US 2020/0148137 A1
(43) Pub. Date: May 14, 2020

(54) THERMAL MANAGEMENT SYSTEM

(71) Applicant: Magna Electronics Inc., Auburn Hills, MI (US)

(72) Inventor: Alan M. Cordeiro, Farmington Hills, MI (US)

(21) Appl. No.: 16/677,722

(22) Filed: Nov. 8, 2019

Related U.S. Application Data
(60) Provisional application No. 62/758,017, filed on Nov. 9, 2018.

(51) Int. Cl. B60R 16/023; G05D 1/00; B60R 16/03; G05D 1/02; H01L 23/34

(52) U.S. Cl. CPC B60R 16/0231; G05D 1/0088; B60R 16/03; B60Y 2306/05; G05D 1/0257; H01L 23/34; G05D 1/0231

(57) ABSTRACT

A vehicular control system includes a plurality of external sensors disposed at a vehicle and having respective fields of sensing exterior of the vehicle, and a control having a data processor that processes data captured by the external sensors for a driving assist function. The control has a maximum junction temperature and an operating junction temperature. A power supply provides power to integrated circuits. The integrated circuits operate at an operating junction temperature below a maximum junction temperature. A thermal management system controls the operating junction temperature of the integrated circuits. The thermal management system reduces the operating junction temperature below the maximum junction temperature in order to reduce the power required by the integrated circuits.

### CROSS REFERENCE TO RELATED APPLICATION

The present application claims the filing benefits of U.S. provisional application Ser. No. 62/758,017, filed Nov. 9, 2018, which is hereby incorporated herein by reference in its entirety.

### FIELD OF THE INVENTION

The present invention relates generally to automotive electronics modules, such as modules that incorporate integrated circuits with small silicon geometries.

### BACKGROUND OF THE INVENTION

Use of imaging sensors and/or non-imaging sensors in vehicular driving assist systems is common and known. Examples of known vision systems are described in U.S. Pat. Nos. 5,949,331; 5,670,935 and/or 5,550,677, which are hereby incorporated herein by reference in their entireties. Automotive electronics modules are often required to operate under harsh external environmental conditions such as ambient temperatures of 85° C. To meet this need, automotive grade integrated circuits are usually rated to operate at higher junction temperatures (e.g., 125° C.). The traditional automotive electronics cooling strategy has been to design cooling components to manage the maximum junction temperatures just below this limit to minimize the cost of the added cooling components.

### SUMMARY OF THE INVENTION

The present invention provides a vehicular control system or driving assistance system or vision system or imaging system for a vehicle that may utilize one or more cameras to capture image data representative of images exterior of the vehicle, and provides a control including an image processor that processes image data captured by the camera. The control may include internal integrated circuits with high levels of silicon density. The internal integrated circuits include a maximum junction temperature and an operating junction temperature. The control system also includes a power supply that provides a required amount of power to the control and integrated circuits and a thermal management system that reduces the operating junction temperature of the integrated circuits. The thermal management system reduces the operating junction temperature below the maximum junction temperature in order to reduce the power required by the integrated circuits. The vehicular control system of the present invention provides an automotive electronics module with one of more integrated circuits with very high levels of silicon density.

These and other objects, advantages, purposes and features of the present invention will become apparent upon review of the following specification in conjunction with the drawings.

### BRIEF DESCRIPTION OF THE DRAWINGS

FIG. 1 is a plan view of a vehicle with a vision system that incorporates cameras including complex integrated circuit components in accordance with the present invention;

FIG. 2 is a chart illustrating typical switching loss and leakage loss for various geometries at maximum junction temperature;

FIG. 3 is an exemplary table of estimated costs of thermal cooling components versus power supply components at various junction temperatures; and

FIG. 4 is a chart illustrating power use and cost of various sub-sections and overall cost at different junction temperatures in accordance with the present invention.

### DESCRIPTION OF THE PREFERRED EMBODIMENTS

A vehicle vision system and/or driving assist system and/or object detection system and/or alert system and/or vehicular control system operates to capture sensor data from the exterior of the vehicle (e.g., images) and may process the captured sensor data to display images and to detect objects at or near the vehicle and in the predicted path of the vehicle, such as to assist a driver of the vehicle in maneuvering the vehicle in a forward or rearward direction. The system includes an image processor or image processing system that is operable to receive image data from one or more cameras and provide an output to a display device for displaying images representative of the captured image data. Optionally, the system may provide display, such as a rearview display or a top down or bird's eye or surround view display or the like. An automated driving control module of the system may run sophisticated algorithms for autonomously controlling the vehicle, such as for controlling steering and braking and accelerating of the vehicle.

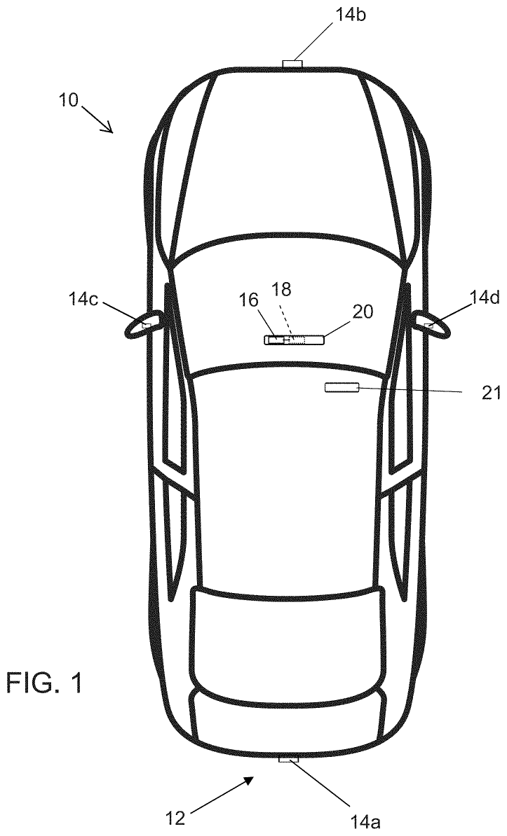

Referring now to the drawings and the illustrative embodiments depicted therein, a vehicle 10 includes an imaging system or vision system 12 that includes at least one exterior viewing imaging sensor or camera, such as a rearward viewing imaging sensor or camera 14a (and the system may optionally include multiple exterior viewing imaging sensors or cameras, such as a forward viewing camera 14b at the front (or at the windshield) of the vehicle, and a sideward/rearward viewing camera 14c, 14d at respective sides of the vehicle), which captures images exterior of the vehicle, with the camera having a lens for focusing images at or onto an imaging array or imaging plane or imager of the camera (FIG. 1). Optionally, a forward viewing camera may be disposed at the windshield of the vehicle and view through the windshield and forward of the vehicle, such as for a machine vision system (such as for traffic sign recognition, headlamp control, pedestrian detection, collision avoidance, lane marker detection and/or the like). The vision system 12 includes a control or electronic control unit (ECU) or processor 18 that is operable to process image data captured by the camera or cameras and may detect objects or the like and/or provide displayed images at a display device 16 for viewing by the driver of the vehicle (although shown in FIG. 1 as being part of or incorporated in or at an interior rearview mirror assembly 20 of the vehicle, the control and/or the display device may be disposed elsewhere at or in the vehicle). The data transfer or signal communication from the camera to the ECU may comprise any suitable data or communication link, such as a vehicle network bus or the like of the equipped vehicle. Optionally, the vehicle may be equipped with an autonomous vehicle control module 21, which may process sensor data from many different sensors or from other intelligent modules to assist in making complex control decisions.

Overall product cost of an electronic module is driven by the cost of all the individual components (e.g., the cost of the electronic components and the cost of the mechanical packaging components). Specifically, the cost of thermal management components and the cost of the power supply components may be significant factors in the overall cost of a system or module.

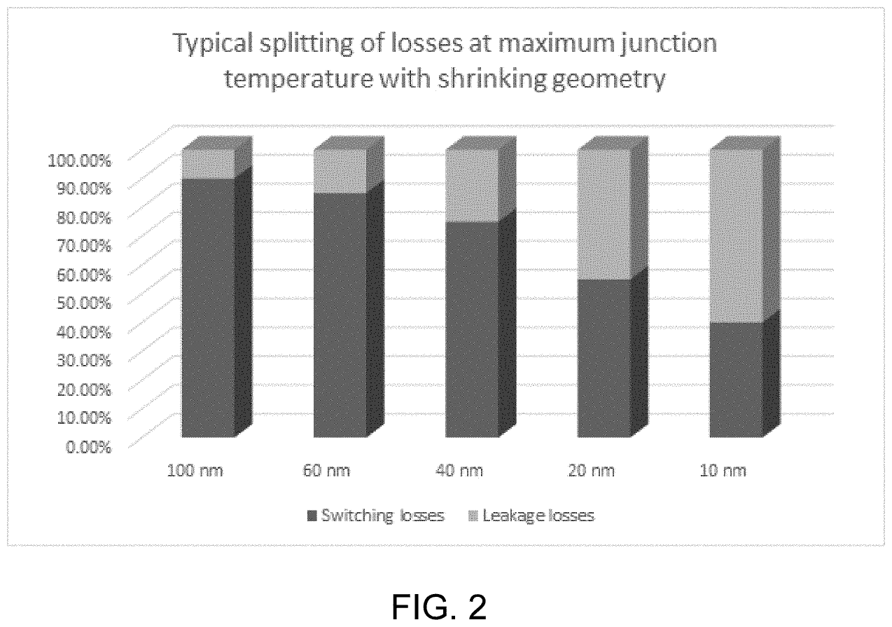

In large complex silicon parts, the overall power consumption primarily consists of switching losses and steady state leakage losses. The ratios between the two losses is dependent upon the geometry or technology node of the silicon (e.g., 100 nm, 20 nm, 10 nm, etc.). In 100 nm silicon geometry, for example, the main contributor to loss is switching loss, which typically accounts for approximately 90 percent of the overall power consumption. However, as silicon geometry continues to shrink, the leakage losses account for a greater share (FIG. 2). For example, leakage losses approach 50% to 60% of the total loss in 20 nm and smaller geometries when the component is operating at the maximum allowable junction temperature seen in most automotive designs (e.g., up to around 125 degrees Celsius). Because the leakage losses increase exponentially with junction temperature, small reductions in operating junction temperature yield significant decreases in overall power consumption.

Typically, cooling of silicon integrated circuits (ICs) is designed to minimize cooling component cost by providing only sufficient thermal management components to barely keep the internal junction temperatures from exceeding the safe limit under worst case external conditions. However, cooling below the maximum junction temperature is desirable because a small amount of extra cooling also has the side effect of reducing power dissipation. This makes the added cost no longer proportional to the amount of temperature reduction gained, but instead the cost will be less. Because reduced power consumption also has a side benefit of reducing power supply costs, the overall total module cost may actually be reduced if design goals are set for targeting lower junction temperatures purposefully.

Exemplary benefits of this implementation include: lower overall module cost; reduced failure rate due to lower junction operating temperature; many other components located inside the module may be selected with lower maximum temperature ratings (because internal module temperatures will be lower); certain components like CMOS imagers will have better overall performance (such as better low light performance) when operated at lower power and temperature. Also, non-volatile memory components sustain longer data retention life when the peak temperature they are exposed to is reduced. Further, dynamic RAM may not have to be refreshed as often at lower temperatures, so their availability improves.

As silicon geometry continues to shrink, the percentage of power losses attributed to leakage continues to become a larger part of the overall losses. Even as semiconductor vendors continue to improve materials to reduce the leakage, the properties of shrinking geometry continue to overwhelm the insulator improvements. Thus, junction temperature has an exponential effect on the amount of leakage loss, and this leakage loss doubles for approximately every 20 degrees increase in junction temperature. Therefore, if the leakage loss is specified at maximum junction temperature, ensuring the vehicular control system keeps the maximum junction temperature 20 degrees cooler will halve the leakage losses, and in the case of a 20 nm part, may offer an overall 22 percent reduction in power consumption. In another example (a 10 nm part), it may offer an up to 30 percent reduction in overall power consumption.

Because the cost of thermal management parts is exponentially proportional to the amount of cooling needed and proportional to the amount of power removed, the cost of cooling the critical semiconductor junctions within, for example, 20 degrees of ambient will be twice that needed to cool it within 40 degrees of ambient. Similarly, the cost to cool the junction to within 10 degrees of ambient will be four times the cost needed to cool it 40 degrees, and twice that needed to cool it 20 degrees. This can be illustrated mathematically in Equation 1 as follows:

$$New Cost = Old Cost * \frac{Original Cooling Delta}{New Cooling Delta} \qquad ( 1 )$$

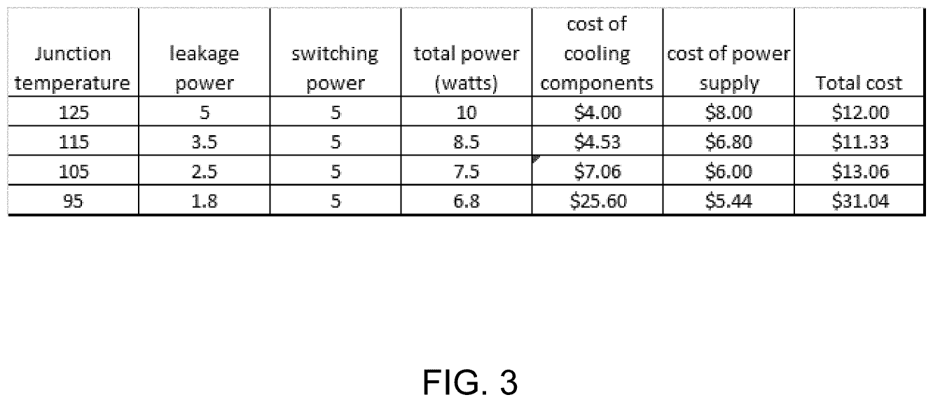

The cost of cooling components is also proportional to the power removed. Thus, removing 5 watts of power may cost half as much as removing 10 watts of power. For examples, as illustrated in the table of FIG. 3, standard cost of cooling components may be $4.00 (e.g., the materials needed to cool the junction to 40 degrees above ambient). This is illustrated mathematically in Equation 2 as follows:

$$New Cost = Old Cost * \frac{New Lower Power}{Original Power} \qquad ( 2 )$$

Equation 3 may represent the combined effects of Equation 1 and Equation 2:

$$New Cost = Old Cost * \frac{Original Cooling Delta}{New Cooling Delta} * \frac{New Lower Power}{Original Power} \qquad ( 3 )$$

Still referring to FIG. 3, when assuming, for example, that the power dissipation for switching losses and leakage losses are each 50 percent of the total loss, the total power dissipated is 10 watts (i.e., 5 watts of switching power and 5 watts of leakage power) and the cost of the power supply is $8.00 (typical power supply cost for this power range), then the total cost is $12.00. As previously discussed, the leakage loss component of total power loss changes exponentially with junction temperature (i.e., it doubles for every 20 degree increase in junction temperature).

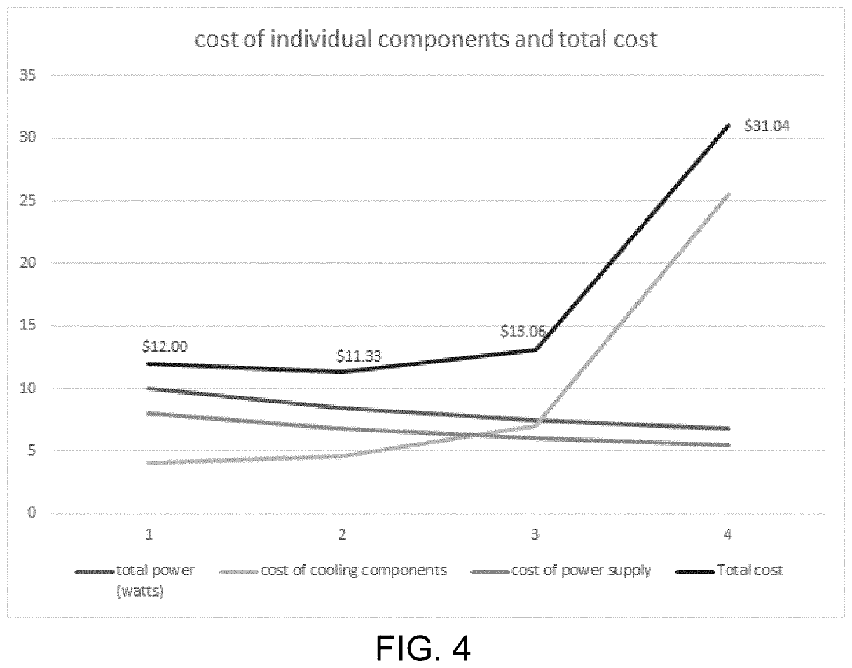

Thus, when assuming a starting cost estimate of $4.00 for the materials needed to cool the junction to 40 degrees above ambient, where ambient is 85 degrees C. and the silicon junction is cooled to 125 degrees C., the table of FIG. 3 and the graph of FIG. 4 illustrate the varying power and cost requirements as the junction temperature is cooled to a range of temperatures. As shown in FIG. 3 and FIG. 4, a junction temperature between 110 to 120 degrees Celsius provides overall lower module costs. In the example shown, a junction temperature of 115 degrees Celsius provides the lowest overall total cost, but this temperature value may vary based on the specific chip and power requirements of the module.

Referring again to FIG. 4, the illustrated examples shows that setting a target design goal of 115 degrees Celsius may give lower overall costs than designing for 125 degrees Celsius. However, when the junction temperature is continued lower to 110 degrees Celsius and 105 degrees Celsius, the optimal point has been past, and the cost begins to increase again. Such a design methodology represents a paradigm shift in how the target temperature is determined. Because the power supply has a smaller power capacity, the chip junction temperature may need to be monitored to ensure it does not exceed the new lower design limit. Optionally, the chip may be shut down when the chip begins to exceed its new desired junction temperature limit.

The reduced cost electrical component may comprise an electrical component of a vehicular driving assist system or vehicular control system, such as a camera module or a control module or device, such as a controller having a data processor, or the like. Optionally, aspects of the reduced cost electrical component may be suitable for use in other vehicular electrical components.

The system includes an image processor operable to process image data captured by the camera or cameras, such as for detecting objects or other vehicles or pedestrians or the like in the field of view of one or more of the cameras. For example, the image processor may comprise an image processing chip selected from the EYEQ family of image processing chips available from Mobileye Vision Technologies Ltd. of Jerusalem, Israel, and may include object detection software (such as the types described in U.S. Pat. Nos. 7,855,755; 7,720,580 and/or 7,038,577, which are hereby incorporated herein by reference in their entireties), and may analyze image data to detect vehicles and/or other objects. Responsive to such image processing, and when an object or other vehicle is detected, the system may generate an alert to the driver of the vehicle and/or may generate an overlay at the displayed image to highlight or enhance display of the detected object or vehicle, in order to enhance the driver's awareness of the detected object or vehicle or hazardous condition during a driving maneuver of the equipped vehicle.

For autonomous vehicles suitable for deployment with the system of the present invention, an occupant of the vehicle may, under particular circumstances, be desired or required to take over operation/control of the vehicle and drive the vehicle so as to avoid potential hazard for as long as the autonomous system relinquishes such control or driving. Such occupant of the vehicle thus becomes the driver of the autonomous vehicle. As used herein, the term “driver” refers to such an occupant, even when that occupant is not actually driving the vehicle, but is situated in the vehicle so as to be able to take over control and function as the driver of the vehicle when the vehicle control system hands over control to the occupant or driver or when the vehicle control system is not operating in an autonomous or semi-autonomous mode.

Typically an autonomous vehicle would be equipped with a suite of sensors, including multiple machine vision cameras deployed at the front, sides and rear of the vehicle, multiple radar sensors deployed at the front, sides and rear of the vehicle, and/or multiple lidar sensors deployed at the front, sides and rear of the vehicle. Typically, such an autonomous vehicle will also have wireless two way communication with other vehicles or infrastructure, such as via a car2car (V2V) or car2x communication system.

The system may utilize a plurality of cameras, such as a CMOS imaging array sensor, a CCD sensor or other sensors or the like, and may utilize aspects of the vision systems described in U.S. Pat. Nos. 5,760,962; 5,715,093; 6,922,292; 6,757,109; 6,717,610; 6,590,719; 6,201,642; 5,796,094; 6,559,435; 6,831,261; 6,822,563; 6,946,978; 7,720,580; 8,542,451; 7,965,336; 7,480,149; 5,877,897; 6,498,620; 5,670,935; 5,796,094; 6,396,397; 6,806,452; 6,690,268; 7,005,974; 7,937,667; 7,123,168; 7,004,606; 6,946,978; 7,038,577; 6,353,392; 6,320,176; 6,313,454 and/or 6,824,281, and/or International Publication Nos. WO 2009/036176; WO 2009/046268; WO 2010/099416; WO 2011/028686 and/or WO 2013/016409, and/or U.S. Publication Nos. US 2010-0020170 and/or US-2009-0244361, which are all hereby incorporated herein by reference in their entireties.

The system may utilize sensors, such as radar or lidar sensors or the like. The sensing system may utilize aspects of the systems described in U.S. Pat. Nos. 9,753,121; 9,689,967; 9,599,702; 9,575,160; 9,146,898; 9,036,026; 8,027,029; 8,013,780; 6,825,455; 7,053,357; 7,408,627; 7,405,812; 7,379,163; 7,379,100; 7,375,803; 7,352,454; 7,340,077; 7,321,111; 7,310,431; 7,283,213; 7,212,663; 7,203,356; 7,176,438; 7,157,685; 6,919,549; 6,906,793; 6,876,775; 6,710,770; 6,690,354; 6,678,039; 6,674,895 and/or 6,587,186, and/or International Publication Nos. WO 2018/007995 and/or WO 2011/090484, and/or U.S. Publication Nos. US-2018-0231635; US-2018-0045812; US-2018-0015875; US-2017-0356994; US-2017-0315231; US-2017-0276788; US-2017-0254873; US-2017-0222311 and/or US-2010-0245066, which are hereby incorporated herein by reference in their entireties.

The system may also communicate with other systems, such as via a vehicle-to-vehicle communication system or a vehicle-to-infrastructure communication system or the like. Such car2car or vehicle to vehicle (V2V) and vehicle-to-infrastructure (car2X or V2X or V21 or a 4G or 5G broadband cellular network) technology provides for communication between vehicles and/or infrastructure based on information provided by one or more vehicles and/or information provided by a remote server or the like. Such vehicle communication systems may utilize aspects of the systems described in U.S. Pat. Nos. 6,690,268; 6,693,517 and/or 7,580,795, and/or U.S. Publication Nos. US-2014-0375476; US-2014-0218529; US-2013-0222592; US-2012-0218412; US-2012-0062743; US-2015-0251599; US-2015-0158499; US-2015-0124096; US-2015-0352953; US-2016-0036917 and/or US-2016-0210853, which are hereby incorporated herein by reference in their entireties.

Changes and modifications in the specifically described embodiments can be carried out without departing from the principles of the invention, which is intended to be limited only by the scope of the appended claims, as interpreted according to the principles of patent law including the doctrine of equivalents.

1. A vehicular control system, said vehicular control system comprising:
a plurality of external sensors disposed at a vehicle and having respective fields of sensing exterior of the vehicle;
a control comprising a data processor that processes data captured by the external sensors for a driving assist function, wherein the control is disposed in the vehicle and comprises integrated circuits;
a power supply that provides power to the integrated circuits;
wherein the integrated circuits operate at an operating junction temperature between 110 degrees Celsius and 120 degrees Celsius, and wherein the operating junction temperature is below a maximum junction temperature;
a thermal management system that controls the operating junction temperature of the integrated circuits; and
wherein operation of the integrated circuits causes electrical switching power losses and electrical leakage power losses, and wherein the electrical leakage power losses is greater than the electrical switching power losses.

2. The vehicular control system of claim 1, wherein the plurality of external sensors comprise sensors selected from the group consisting of (i) a plurality of cameras, (ii) a plurality of radar sensors and (iii) a plurality of lidar sensors.

3. The vehicular control system of claim 1, wherein the electrical leakage power losses comprise more than half of the combined electrical leakage power losses and the electrical switching power losses.

4. The vehicular control system of claim 1, wherein at least some of the integrated circuits comprise semiconductor components having a geometry of less than or equal to 20 nm.

5. The vehicular control system of claim 1, wherein at least some of the integrated circuits comprise transistors having a geometry of less than or equal to 20 nm.

6. The vehicular control system of claim 1, wherein a cooling device is incorporated into the thermal management system for reducing an ambient temperature near the integrated circuits.

7. The vehicular control system of claim 6, wherein reducing the ambient temperature near the integrated circuits via the cooling device allows other components of the vehicular control system to comprise lower temperature rated components.

8. The vehicular control system of claim 7, wherein reducing the ambient temperature near the integrated circuits via the cooling device reduces a predicted failure rate of other components of the vehicular control system.

9. The vehicular control system of claim 1, wherein the control, responsive to processing data captured by the plurality of external sensors, generates an output for autonomously controlling the vehicle.

10. A vehicular control system, said vehicular control system comprising:
a plurality of external sensors disposed at a vehicle and having respective fields of sensing exterior of the vehicle;
a control comprising a data processor that processes data captured by the external sensors for a driving assist function, wherein the control is disposed in the vehicle and comprises integrated circuits;
a power supply that provides power to the integrated circuits;
wherein the integrated circuits operate at an operating junction temperature below a maximum junction temperature;
a thermal management system that controls the operating junction temperature of the integrated circuits;
wherein at least some of the integrated circuits comprise semiconductor components having a geometry of less than or equal to 20 nm; and
wherein the control, responsive to processing data captured by the plurality of external sensors, generates an output for autonomously controlling the vehicle.

11. The vehicular control system of claim 10, wherein the operating junction temperature is a temperature between 110 degrees Celsius and 120 degrees Celsius.

12. The vehicular control system of claim 10, wherein operation of the integrated circuits causes electrical switching power losses and electrical leakage power losses, and wherein the electrical leakage power losses is greater than the electrical switching power losses.

13. The vehicular control system of claim 10, wherein the plurality of external sensors comprise sensors selected from the group consisting of (i) a plurality of cameras, (ii) a plurality of radar sensors and (iii) a plurality of lidar sensors.

14. The vehicular control system of claim 10, wherein a cooling device is incorporated into the thermal management system for reducing an ambient temperature near the integrated circuits.

15. The vehicular control system of claim 14, wherein reducing the ambient temperature near the integrated circuits via the cooling device allows other components of the vehicular control system to comprise lower temperature rated components.

16. The vehicular control system of claim 15, wherein reducing the ambient temperature near the integrated circuits via the cooling device reduces a predicted failure rate of other components of the vehicular control system.

17. A vehicular control system, said vehicular control system comprising:
a plurality of external sensors disposed at a vehicle and having respective fields of sensing exterior of the vehicle;
a control comprising a data processor that processes data captured by the external sensors for a driving assist function, wherein the control is disposed in the vehicle and comprises integrated circuits;
a power supply that provides power to the integrated circuits;
wherein the integrated circuits operate at an operating junction temperature between 110 degrees Celsius and 120 degrees Celsius, and wherein the operating junction temperature is below a maximum junction temperature of 125 degrees Celsius;
a thermal management system that controls the operating junction temperature of the integrated circuits;
wherein operation of the integrated circuits causes electrical switching power losses and electrical leakage power losses, and wherein the electrical leakage power losses is greater than the electrical switching power losses;
wherein at least some of the integrated circuits comprise semiconductor components having a geometry of less than or equal to 20 nm; and
wherein the control, responsive to processing data captured by the plurality of external sensors, generates an output for autonomously controlling the vehicle.

18. The vehicular control system of claim 17, wherein a cooling device is incorporated into the thermal management system for reducing an ambient temperature near the integrated circuits.

19. The vehicular control system of claim 18, wherein reducing the ambient temperature near the integrated circuits via the cooling device (i) allows other components of the vehicular control system to comprise lower temperature rated components and (ii) reduces a predicted failure rate of other components of the vehicular control system.

20. The vehicular control system of claim 17, wherein the plurality of external sensors comprise sensors selected from the group consisting of (i) a plurality of cameras, (ii) a plurality of radar sensors and (iii) a plurality of lidar sensors.
